(19) United States
(12) Patent Application Publication
(10) Pub. No.: US 2012/0304934 A1
(43) Pub. Date: Dec. 6, 2012

(54) POROUS CERAMIC GAS DISTRIBUTION FOR PLASMA SOURCE ANTENNA

(75) Inventor: John M. White, Hayward, CA (US)

(73) Assignee: Applied Materials, Inc., Santa Clara, CA (US)

(21) Appl. No.: 13/480,062

(22) Filed: May 24, 2012

Related U.S. Application Data
(60) Provisional application No. 61/492,607, filed on Jun. 2, 2011.

(51) Int. Cl. H01J 7/20; H01J 17/04; C23C 16/50

(52) U.S. Cl. 118/723 R; 313/231.31; 315/111.21

(57) ABSTRACT

Apparatus and methods for preventing or substantially minimizing unwanted deposits on dielectric covers of an antenna by effectively providing an inert (non-depositing) gas at the surface of the antenna cover is provided.

### CROSS REFERENCE TO RELATED APPLICATIONS

This application claims benefit of U.S. Provisional Application Ser. No. 61/492607, filed Jun. 2, 2012, which is incorporated by reference in its entirety.

### BACKGROUND

1. Field

Embodiments of the present invention are generally relates to plasma processing of substrates, and more specifically, to generating a plasma using antennas positioned in a plasma processing chamber.

2. Description of the Related Art

When processing large area substrates, antennas and coils are often used to produce plasmas that are useful in large-area thin-film deposition and etching. The antennas are often immersed in the plasma to gain the benefit of having an efficient electromagnetic coupling between the antenna and the plasma and to circumvent having to use large and/or many dielectric “windows”, which would allow the antennas to be placed outside the chamber/plasma volume. However, the presence of antennas in the plasma causes unwanted deposits to form on the exposed surface of the antenna or its dielectric covering if such a covering is employed.

Traditionally, a non-depositing gas is directed at the exposed surface of the antenna to prevent reacting gases from depositing on the antennas. However, directing a non-depositing gas towards the antenna is only marginally effective in preventing deposition due to gas diffusion. Additionally, the surfaces of the tubes or nozzles for delivering the non-depositing gases also collect deposits on themselves. As shown in FIG. 1, a conventional antenna 102 is surrounded by a quartz tube 104 and positioned in a chamber volume. A non-depositing delivery nozzle 108 is positioned close to the quartz tube 104. The non-depositing delivery nozzle 108 is configured to provide a flow of non-depositing gas for the purpose of preventing deposition gas from depositing on the quartz tube 104. However, undesirable depositions 106 nevertheless formed on the quartz tube 104 and the non-depositing delivery nozzle 108.

Thus, there is a need for a plasma chamber with improved antennas for generating plasmas to process large area substrates.

### SUMMARY

Embodiments of the present invention are generally relates to plasma processing of substrates, and more specifically, to generating a plasma using antennas positioned in a plasma processing chamber.

One embodiment provides an antenna assembly for generating a plasma. The antenna assembly includes an antenna configured to energize one or more processing gases to generate a plasma when connected to a power supply, and a porous cover surrounding and spaced from the antenna. The porous cover is formed from a dielectric material. An inner volume is defined between the antenna and porous cover. The porous cover allows a gas pressurizing the inner volume to diffuse therethrough, thereby reducing unwanted deposition on the antenna assembly.

Another embodiment provides a plasma processing chamber. The plasma processing chamber includes a chamber body having a processing volume defined therein, a substrate support disposed in the processing volume, a processing gas delivery assembly configured to deliver one or more processing gas to the processing volume, and a plurality of antenna assemblies disposed in the processing volume. Each antenna assembly includes an antenna configured to generate a plasma in the processing volume, and a porous cover surrounding and spaced from the antenna. The porous cover is formed from a dielectric material. An inner volume is defined between the antenna and porous cover. The plasma processing chamber further includes a non-depositing gas source connected to the inner volume of each antenna assembly. The non-depositing gas source is operable to pressurize the inner volume with a non-depositing gas to drive the non-depositing gas in the inner volume to the processing volume through the porous cover.

Yet another embodiment provides a method for generating a plasma in a processing chamber. The method includes pressurizing an inner volume of an antenna assembly disposed in a processing volume of the processing chamber with a non-depositing gas so that the non-depositing gas diffuses through a porous cover of the antenna assembly. The antenna assembly comprises an antenna disposed in the inner volume bounded by the porous cover. The method further includes flowing one or more processing gas to the processing volume, and applying a power to the antenna to generate a plasma in the processing volume.

### BRIEF DESCRIPTION OF THE DRAWINGS

So that the manner in which the above recited features of the present disclosure can be understood in detail, a more particular description, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a sectional view of a conventional antenna positioned in a plasma processing chamber.

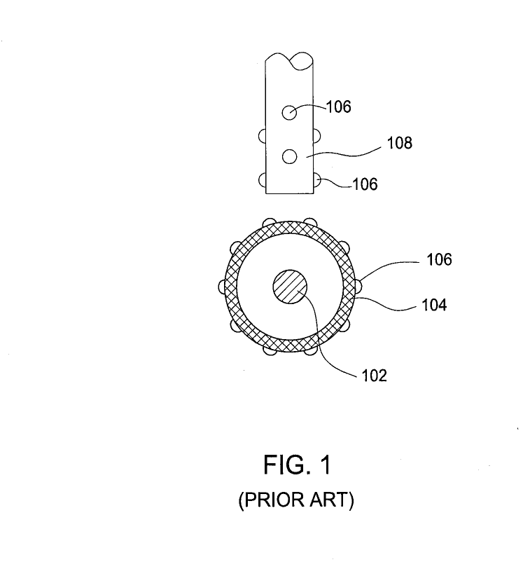

FIG. 2 is a cross-sectional view of an illustrative plasma processing chamber according to one embodiment of the present invention.

FIG. 3 is an enlarged sectional top view of an antenna assembly according to one embodiment of the present invention.

FIG. 4 is a sectional view of the antenna assembly of FIG. 3.

FIG. 5 is a partial sectional view of an antenna assembly according to another embodiment of the present invention.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the present invention are generally relates to plasma processing of substrates, and more specifically, to generating a plasma using antennas positioned in a plasma processing chamber. Embodiments of the present invention provides apparatus and methods for preventing or substantially minimizing unwanted deposits on dielectric covers of an antenna by effectively providing an inert (non-depositing) gas through a porous material forming the antenna cover.

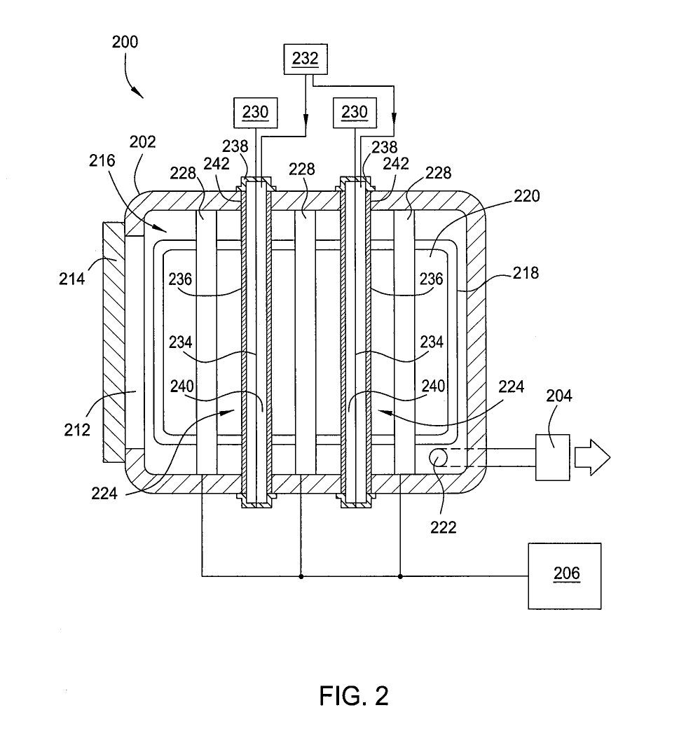

FIG. 2 is a sectional view of a plasma processing chamber 200 having a plurality of antenna assemblies 224 according to one embodiment of the invention. The plasma processing chamber 200 includes a chamber body 202 coupled to a pumping system 204, a processing gas delivery system 206 and one or more power sources 230 for plasma generation. The chamber body 202 defines a processing volume 216. A substrate support 218 is disposed in the processing volume 216. The substrate support 218 holds a substrate 220 during processing. A slit valve passage 212 is formed through the chamber body 202 to allow entry and egress of the substrate 220 from the processing volume 216. The slit valve passage 212 is selectively sealed by a slit valve 214.

A pumping port 222 is formed in the chamber body 202 and coupled to the pumping system 204. The pumping system 204 is utilized to regulate the pressure within the processing volume 216, and to remove process by-products during processing of the substrate 220.

The processing gas delivery system 206 is connected to a plurality of gas delivery tubes 228. Processing and other reactive gases are provided into the processing volume 216 through the plurality of gas delivery tubes 228. Each of the plurality of gas delivery tubes 228 may have a plurality of apertures formed therethrough to allow processing gases provided by the processing gas delivery system 206 to enter the processing volume 216.

The plurality of antenna assemblies 224 are disposed in the processing volume 216 of the chamber body 202. Each of the plurality of antenna assemblies 224 is connected to the power source 230 and is configured to energize gases within the processing volume 216. In one embodiment, the plurality of antenna assemblies 224 traverse the processing volume 216 and are arranged in a parallel manner. However, other arrangements are contemplated.

Each antenna assembly 224 includes an antenna 234 and a gas permeable porous cover 236. The porous cover 236 surrounds and is spaced from the antenna 234. The antenna 234 is connected to the power source 230 and traverses the processing volume 216. In one embodiment, the porous cover 236 is a tube surrounding the antenna 234 so that the antenna 234 is not directly exposed to the processing volume 216.

An inner volume 240 is defined between the antenna 234 and porous cover 236. A non-depositing gas source 232 is in fluid connection with the inner volume 240. The non-depositing gas source 232 is configured to pressurize the inner volume 240 with one or more non-depositing gases which surround the antenna. During processing, the pressurized non-depositing gas in the inner volume 240 is driven by the non-depositing gas source 232 into the processing volume 216 through pores in the porous cover 236. The non-depositing gas source 232 may be a source of any gas that does not form undesired deposition on the porous cover 236. In one embodiment, the non-depositing gas comprises at least one of argon, ammonia and nitrogen.

The porous cover 236 may be formed of dielectric porous gas permeable material compatible with a plasma environment. In one embodiment, the porous cover 236 is formed from a porous gas permeable dielectric ceramic. In one embodiment, the porous cover 236 may be a circular tube surrounding the antenna 234 in a coaxial manner.

In one embodiment, the porous cover 236 may be a long porous ceramic tube extending across the processing volume 216 through openings 242 formed through the chamber body 202. For example, the porous cover 236 may extend from one side to the opposite side of the chamber body 202.

In one embodiment, covers 238 may be coupled to chamber body 202 to cover and seal the openings 242 and enclose (i.e., prevent leakage from) the inner volume 240.

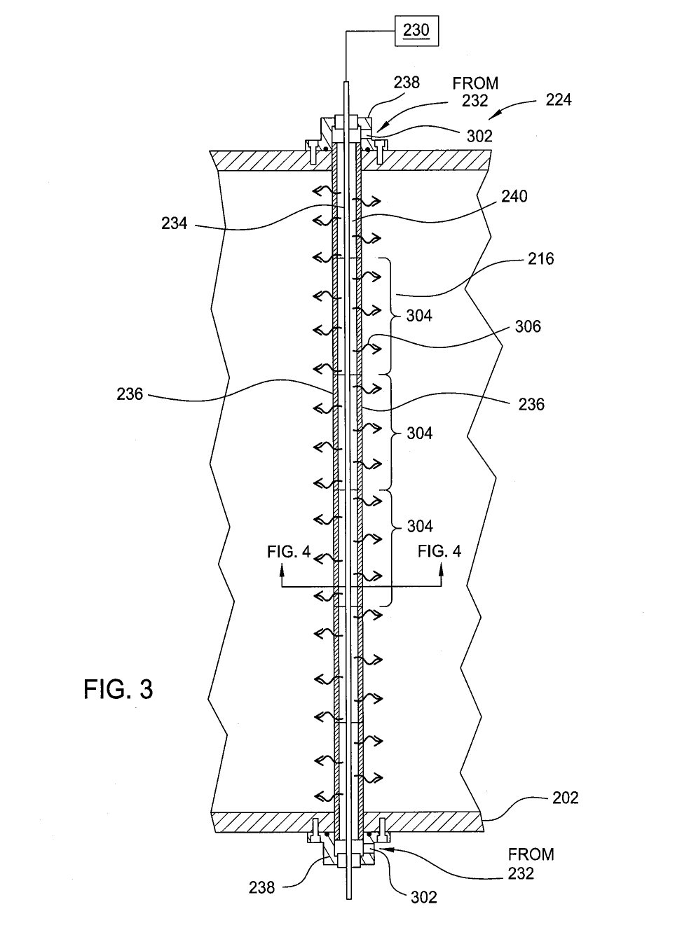

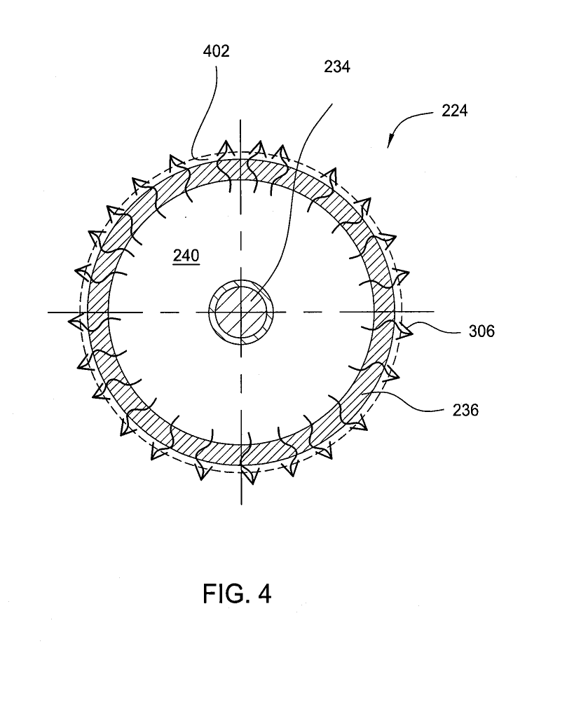

FIG. 3 is an enlarged sectional top view of the antenna assembly 224 and FIG. 4 is an enlarged sectional view of the antenna assembly 224.

In one embodiment, the porous cover 236 may be one tube long enough to traverse across the entire processing volume 216. Alternatively, the porous cover 236 may be formed by multiple cover segments 304 joined or abutted together. In one embodiment, the cover segments 304 may be co-axially stacked together by close-fitting joints to minimize leakage between adjacent cover segments 304.

The non-depositing gas source 232 may be connected to the inner volume 240 through at least one inlet 302 formed at at least one of the end covers 238. In one embodiment, inlets 302 are formed in opposite covers 238 to ensure the entire elongated inner volume 240 can be evenly processed along the Hs length.

During processing, the non-depositing gas source 232 first provides a non-depositing gas to and pressurizes the inner volume 240 of the plurality of antenna assemblies 224. The non-depositing gas in the inner volume 240 diffuses through the porous cover 236 to the processing volume 216 as shown by arrows 306 in FIGS. 3 and 4.

One or more processing gases can then be supplied to the processing volume 216 from the processing gas delivery system 206. The pressure in the inner volume 240, which is greater than the pressure within the processing volume 216, prevents the one or more processing gases in the processing volume 216 from entering the inner volume 240 through the porous cover 236.

Power may be applied to the antenna 234 to generate plasma of the one or more processing gases in the processing volume 216 for plasma processing. The pressure in the inner volume 240 prevents plasma discharge of the non-depositing gases in the inner volume 240. However, the non-depositing gases around in area 402 immediately surrounding the porous cover 236 are discharged and form a plasma in the area 402, as shown in FIG. 4. The plasma in the area 402 is composed substantially just of the dissociated non-depositing gas introduced through the porous cover 236, thereby preventing the diffusion of depositing gases to the surface of the porous cover 236 and thus avoiding unwanted deposits thereon.

In one embodiment, argon is used as non-depositing gas when the antenna 234 is a co-axial microwave plasma source, and argon is provided to the inner volume 240 of each antenna assembly 224. The area 402 immediately surrounding the porous cover 236 would be occupied by substantially pure argon when the inner volume 240 is pressurized with argon. Because argon is especially easy to dissociate, a plasma from relatively pure argon would be generated in area 402, thus, promoting discharge and deposition uniformity in along the length of the antenna assembly 224.

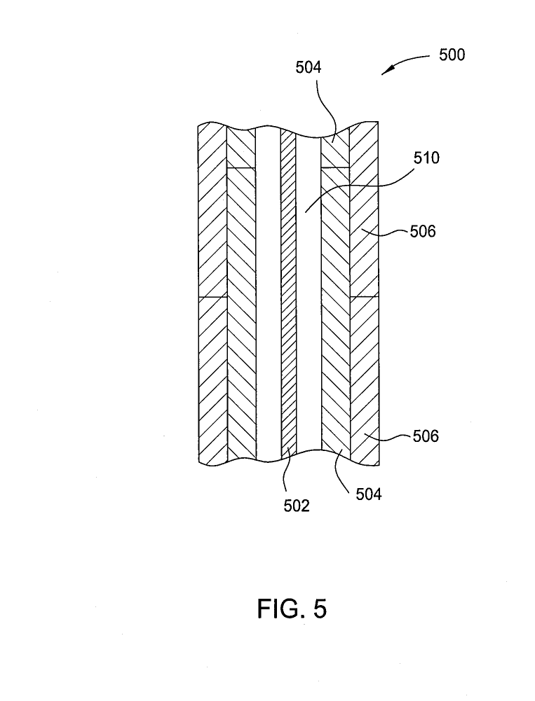

FIG. 5 is a partial sectional view of an antenna assembly 500 according to another embodiment of the present invention. The antenna assembly 500 is similar to the antenna assembly 224 described above. The antenna assembly 500 includes a porous cover 506 defining an inner volume 510. An antenna 502 is disposed in the inner volume 510. Similar to the porous cover 236, the porous cover 506 surrounds the antenna 502 in a coaxial manner.

The antenna assembly 500 further includes a porous liner 504 disposed immediately inside the porous cover 506. The porous liner 504 may be formed by a porous dielectric media or tube. The porous liner 504 is configured to further reduce leakage and prevent plasma discharge inside the inner volume 510 by producing sufficiently high pressure in the inner volume 510. In one embodiment, the porous liner 504 has a higher flow resistance than the porous cover 506.

As discussed above, embodiment of the present invention provide a substantially coaxial arrange of an electrical antenna and a porous dielectric cover disposed within a plasma processing chamber. Non-depositing gas(es) is introduced to a plasma volume of the plasma processing chamber by internally pressurizing and forcing the non-depositing gas through the porous dielectric antenna cover.

Embodiments of the present invention have various advantages. Particularly, the non-depositing gas exiting the surface of the porous antenna cover prevents the diffusion of depositing gases to the surface of the cover, thus avoiding unwanted deposits thereon. Additionally, pressurized non-depositing gas also improves processing uniformity when coaxial microwave plasma sources are used with embodiments of the present invention. Particularly, when argon is used as non-depositing gas.

Even though a plasma processing chamber for processing large area substrates is described above, embodiments of the present invention can be used in any plasma source which is immersed in a plasma chamber and runs processes which have a tendency to produce unwanted deposits on the gas distribution and plasma source hardware elements.

Embodiments of the present invention may be used in any plasma generating technologies, such as RF, VHF, UHF and microwave plasma generation.

While the foregoing is directed to embodiments of the present invention, other and further embodiments of the invention may be devised without departing from the basic scope thereof, and the scope thereof is determined by the claims that follow.

1. An antenna assembly for generating a plasma, comprising:
an antenna; and
a gas permeable porous cover surrounding and spaced from the antenna, wherein the porous cover is formed from a dielectric material.

2. The antenna assembly of claim 1, wherein the porous cover is an elongated tube, and the antenna and the porous cover are coaxially positioned.

3. The antenna assembly of claim 2, wherein the porous cover comprises a plurality of co-axial tube segments stacked together.

4. The antenna assembly of claim 3, further comprising a porous liner disposed inside the porous cover.

5. The antenna assembly of claim 1, further comprising two end covers enclosing the inner volume, wherein a gas inlet is formed through at least one of the end covers.

6. A plasma processing chamber comprising:
a chamber body having a processing volume defined therein;
a substrate support disposed in the processing volume;
a processing gas delivery assembly configured to deliver one or more processing gas to the processing volume;
a plurality of antenna assemblies disposed in the processing volume, wherein each antenna assembly comprises:
an antenna configured to generate a plasma in the processing volume; and
a gas permeable porous cover surrounding the antenna and defining an inner volume therebetween, wherein the porous cover is formed from a dielectric material; and
a non-depositing gas source connected to the inner volume of each antenna assembly.

7. The plasma processing chamber of claim 6, wherein the porous cover is an elongated tube, and the antenna and the porous cover are coaxially positioned.

8. The plasma processing chamber of claim 7, wherein the plurality of antenna assemblies traverse the processing volume in a parallel manner.

9. The plasma processing chamber of claim 7, wherein each antenna assembly further comprises:
two end covers enclosing the inner volume, wherein a gas inlet is formed through each end cover and connected to the non-depositing gas source.

10. The plasma processing chamber of claim 6, wherein the porous cover comprises a plurality of tube segments stacked together.

11. The plasma processing chamber of claim 10, further comprising a porous liner disposed inside the porous cover.

12. A method for generating a plasma in a processing chamber, comprising:
pressurizing an inner volume of an antenna assembly disposed in a processing volume of the processing chamber with a non-depositing gas, the non-depositing gas diffusing through a porous cover of the antenna assembly into the processing volume;
flowing one or more processing gas to the processing volume; and
applying a power to an antenna surrounded by the porous cover to generate a plasma in the processing volume.

13. The method of claim 12, wherein pressurizing the inner volume comprising delivering gas comprising at least one of argon, ammonia and nitrogen to the inner volume.

14. The method of claim 12, wherein applying a power to the antenna comprises applying a RF, VHF, UHF, or microwave power to the antenna.

15. The method of claim 12, wherein the antenna assembly has an elongated shape with two ends, and pressurizing the inner volume comprises delivering the non-depositing gas through inlets formed at the two ends of the antenna assembly.

16. The method of claim 12, wherein pressurizing the inner volume comprising delivering argon to the inner volume.

17. The method of claim 16, wherein applying a power to the antenna comprises applying a microwave power to the antenna.
